(19) United States
(12) Patent Application Publication
(10) Pub. No.: US 2026/0195512 A1
(43) Pub. Date: Jul. 9, 2026

(54) SYSTEM AND METHOD FOR EXTRACTING AMPLITUDE-VERSUS-ANGLE OR OFFSET INFORMATION FROM SEISMIC DATA

(71) Applicant: CGG SERVICES SAS, Massy Cedex (FR)

(72) Inventors: Andrew RATCLIFFE, Henfield (GB); Gordon POOLE, East Grinstead (GB); James COOPER, Redhill (GB)

(21) Appl. No.: 19/130,585

(22) PCT Filed: Jan. 11, 2024
(86) PCT No.: PCT/IB2024/000014

§ 371 Date: May 16, 2025

Related U.S. Application Data
(60) Provisional application No. 63/479,806, filed on Jan. 13, 2023.
(60) Provisional application No. 63/479,807, filed on Jan. 13, 2023.

(51) Int. Cl. G06F 30/28

(52) U.S. Cl. CPC G06F 30/28

(57) ABSTRACT

A method for extracting amplitude-versus-reflection angle, or amplitude-versus-offset information from input data, includes receiving the input data d, receiving an initial earth model V that includes at least a pressure-wave velocity vₚ, calculating an updated, extended domain earth model Vₑ based on the input data d, and the initial earth model V, using a full waveform inversion process, where the updated, extended domain earth model Vₑ is expressed in an extended domain, transforming the updated, extended domain earth model Vₑ from the extended domain to an ordinary domain, to obtain an ordinary domain updated earth model, extracting the amplitude-versus-reflection angle or amplitude-versus-offset information from the ordinary domain updated earth model; and generating an image of a subsurface that is indicative of the formation in the subsurface, based on the extracted amplitude-versus-reflection angle or amplitude-versus-offset information.

### BACKGROUND OF THE INVENTION

### Technical Field

Embodiments of the subject matter disclosed herein generally relate to a system and method for processing recorded seismic data for extracting amplitude-versus-angle (AVA) or amplitude-versus-offset (AVO) information, and more particularly, to various methods for using a Full Waveform Inversion (FWI) processing or its variants for extracting the AVA or AVO information.

### Discussion of the Background

Hydrocarbon exploration and development uses waves (e.g., seismic waves or electromagnetic waves) to explore the structure of underground formations on land and/or at sea (i.e., formations under the seafloor). As schematically illustrated in FIG. 1, waves emitted by a source 110 at a known location penetrate an explored formation 112-127 and are reflected, refracted or diffracted at interfaces 112, 122, 124, 126 that separate the formation's layers 121, 123, 125, 127 having different layer properties. Sensors 130 (only one is shown for simplicity), which may be towed by a boat 132 as streamers, or may be independently placed in the water or ocean bottom (not shown), detect the waves 140 (primaries) and 150 (multiples) and record one or more of their characteristics, for example, pressure, one-dimensional displacement, three-dimensional displacement, etc. Note that, as used herein, the term “formation” refers to any geophysical structure into which source energy is used to perform seismic surveying, e.g., land, ocean bottom, transition zone or marine based. This means that the configuration shown in FIG. 1 may also be used on land, in which case the source 110 is carried by a truck or other means from one point to another, and the sensors 130 are located on the surface, or buried in the subsurface. Note that the sensors 130 are known in the art and they can include hydrophones, accelerometers, geophones, gravitational sensors, electromagnetic sensors, etc.

In order to understand the structure of the explored underground formation (layers 121, 123, 125, and 127 and interfaces 112, 122, 124, and 126 in the specific example of FIG. 1), various steps are performed on the data “d” recorded by sensors 130, as part of the processing of the recorded seismic data. One of those steps is FWI. FWI is a technique for deriving high-resolution models “V” of the subsurface (Earth) parameters (e.g., pressure-wave velocity “vₚ”, shear-wave velocity “vₛ”, viscosity, density “ρ”, impedance, reflectivity, anisotropy, etc.), from seismic data recordings d. The model V may include one or more of these earth parameters, which are referred to herein using the general terms “velocity model” or “earth model” or “model.”

FWI is a nonlinear inversion scheme with the objective of determining subsurface properties for the model V which minimize a misfit between the observed/recorded/measured seismic data d (also described interchangeably as real or field data here) and synthetic or modelled data, which is calculated/estimated from a candidate model V, which is an earth model or a model of the earth parameters. These earth models could have been calculated using, for example, travel time tomography on the seismic data (for example, Bishop, T. N., Bube, K. P., Cutler, R. T., Langan, R. T., Love, P. L., Resnick, J. R., Shuey, R. T, Spindler, D. A., and Wyld, H. W. Tomographic determination of velocity and depth in laterally varying media, Geophysics, 50 (6), 903-923), previous implementations of FWI on the seismic data, or well log information.

The misfit is commonly defined by an objective function that measures the least-squares data difference between the observed d and modelled data “p” (i.e., data calculated, for example, as discussed in Virieux, J., and Operto, S. An overview of full-waveform inversion in exploration geophysics: Geophysics, 74, no. 6, WCC1-WCC26). Other misfit functions may be used in the full waveform inversion, for example, an optimal transport (see, Poncet, R., J. Messud, M. Bader, G. Lambaré, G. Viguier, and Hidalgo, C. [2018] FWI with Optimal Transport: a 3D Implementation and an application on a Field Dataset. 80th EAGE Conference & Exhibition, Expanded Abstracts, We A12 02), an adaptive waveform (see, Warner, M. and Guasch, L. [2014] Adaptive Waveform Inversion-FWI Without Cycle Skipping—Theory. 76th EAGE Conference & Exhibition, Extended Abstracts, We E106 13), a dynamic warping (see, Wang, M., Y. Xie, W. Q. Xu, K. F. Xin, B. L. Chuah, F. C. Loh, T. Manning, and Wolfarth, S. [2016] Dynamic-warping full-waveform inversion to overcome cycle skipping. 86th SEG Annual International Meeting, Expanded Abstracts, 1273-1277), a partial matching (see, Cooper, J., Ratcliffe, A. and Poole, G. [2021] Mitigating cycle skipping in full-waveform inversion using partial matching filters. 82nd EAGE Conference & Exhibition, Extended Abstracts, p 1-5), or a time-lag (see, Zhang, Z., J. Mei, F. Lin, R. Huang, and Wang, P. [2018] Correcting for salt misinterpretation with full-waveform inversion: 88th SEG Annual International Meeting, Expanded Abstracts, 1143-1147) misfit function.

The term modelled data p refers to the synthetic data obtained from an earth model V. FWI is an iterative approach requiring an a priori initial model, which is then repeatedly updated via an inversion algorithm. In an ideal case, the updated model V will converge to the true model representing the observed data d. An exemplary flow of a conventional FWI process is presented in FIG. 2. This process starts by receiving in step 200 the initial velocity model, and in step 210, the recorded data d. Optionally, in step 205, the method may receive additional information about the surface, for example, anisotropy parameters, which are known from other surveys or methods. Then, the FWI performs step 220 for generating the synthetic data set p, based on the model V and, optionally, the recorded data d, followed by the step 230 of updating the current model V based on a comparison (that involves the objective function) between the synthetic data p and the recorded data d. The steps 220 and 230 are iteratively performed until a loop-exiting criterion, LEC, is met in step 232. The LEC may be related to a model's convergence or simply a predetermined number of iterations. In the case of complex models with multiple non-independent parameters, different subsets of the parameter values may be updated at different iterations. Then, the method generates in step 240 an image of the subsurface domain based on the updated model.

The nonlinear inversion problem discussed with regard to FIG. 2 connects the candidate earth model V, a propagating modelled wavefield, w, (simply called the “wavefield” herein; usually the wavefield propagates from a source to a receiver where the data d is recorded; data d is extracted from the wavefield w) and the modelled data p (extracted from w using a sampling operator, s) via a nonlinear forward operator G as follows:

$$G ( V ) = p = s ( w ) . \qquad ( 1 )$$

The operator G describes how to generate the synthetic data corresponding to the given model V. As such, it represents a propagation of a seismic source, or sources, through a medium described by V, according to a known wave equation, with extraction of the resulting wavefield, w, at the receiver locations, via the sampling operator, s. If M represents the true Earth model, and d the known observed data extracted from the real wavefield travelling through the true Earth model, it is possible to write, based on equation (1), that:

$$G ( M ) = d . \qquad ( 2 )$$

The inversion scheme on which FWI is based, aims to find a model V which minimizes the misfit between the modelled data p of equation (1) and the observed data d of equation (2), typically in a least-squares sense. Iterative gradient-based inversion algorithms such as Steepest Descent, Conjugate Gradient, or Limited-memory Broyden-Fletcher-Goldfarb-Shanno (LBFGS) may be used to solve the inversion problem. However, alternate inversion schemes exist.

With conventional seismic data processing, pre-stack migrated data are often used in analyses of AVA or AVO effects of reflection data, which can be indicators of hydrocarbons in the subsurface, where the estimated AVO or AVA parameters may relate to an amplitude intercept and an amplitude gradient with offset or angle. More specifically, AVO is related to the amplitude of a seismic attribute that is measured with the sensor 130, versus the distance (the offset) between the source 110 and the sensor 130. AVA is related to the amplitude of a seismic attribute that is measured with the sensor 130, versus the incident angle of the seismic wavefield at the reflection point generating the seismic attribute. The AVA or AVO analysis is a technique that reveals rock's fluid content, porosity, density or seismic velocity, and these parameters are then used to infer the location of hydrocarbons in the subsurface. The relations between the reflection coefficients and the angle of incidence of the seismic waves in the subsurface is known and described by the Zoeppritz equations. Other theories or equations may be used for linking these two concepts, for example, the Aki-Richards equations or the Shuey equation. Irrespective of which equations are used, wave propagation in the real Earth is described most accurately by the elastic (or visco-elastic) wave equation. However, the use of elastic wave propagators is known to be an expensive process, and more expensive than the use of acoustic wave propagators. Traditional FWI approaches are based only on the acoustic, or visco-acoustic, wave-propagation and often do not represent the amplitude behaviour accurately enough to be used as a hydrocarbon indicator. A number of existing solutions to this problem have been proposed and are briefly discussed below.

One solution is elastic FWI. For this case, the process inverts for, or honours, an existing, elastic, shear-wave, velocity vₛ, as well as the acoustic, pressure-wave, velocity vₚ. The presence of non-zero shear-wave velocity vₛ will result in more accurate amplitudes in the data modelled during the inversion, thus leading to a more accurate amplitude variation with the reflection angle of the modelled data. This means that this approach results in an inverted earth model that more accurately describes the real Earth. While in theory this approach sounds appealing, elastic FWI is very expensive to run to high frequencies and also the multi-parameter nature of the approach may result in leakage between the inverted vₚ and vₛ models.

Another approach relies on using an augmented acoustic wave equation. As proposed by McLeman et al. (McLeman, J., Burgess, T., Sinha, M., Hampson, G. and Thompson, T. [2021] Reflection FWI with an augmented wave equation and quasi-Newton adaptive gradient scheme. First International Meeting for Applied Geoscience & Energy, Expanded Abstracts, 667-671.) and Burgess et al. (see, International Patent Application WO 2021/252693), this approach adds terms to the conventional acoustic wave equation in an attempt to mimic elastic amplitude behaviour. The authors of this work claim that these modifications allow AVA information to be derived directly as an output of their acoustic FWI process. The physical justification for this approach is not completely clear and, for example, one can no longer derive this augmented acoustic wave from the more general elastic wave equation which governs the wave propagation in the Earth.

Yet another approach uses applications of acoustic FWI at different reflection angles. As explained in Yang et al. (U.S. Pat. No. 10,520,619) and Warner et al. (Warner, M., J. Armitage, A. Umpleby, N. Shah, H. Debens, F. Mancini [2022] AVO DETERMINATION USING ACOUSTIC FWI. 83rd EAGE Conference & Exhibition, Extended Abstracts, p 1-5), this approach involves running acoustic FWI for input data restricted to different reflection angles, or offsets. The FWI approaches may include velocity and/or density inversions, where each inversion only needs to satisfy the input data within a given angle, or offset, range. The data may be subsequently corrected from its zero-angle amplitude following Yang et al. or Warner et al. Angle-dependent wavelet corrections may be made following Yang et al. One issue in these approaches is that one needs to convert from the surface offset acquisition domain into the subsurface reflection angle domain. In a simple 1D earth model, this transform can be easily done using a straight-ray approximation and Snell-Dix ray bending. For earth models with moderate 3D complexity, ray-tracing can then be performed. However, in complex 3D models, even ray-tracing can become inaccurate. There also exists the possible complication of whether this conversion from offset to angle is done on the data before or after the FWI process.

Thus, there is a need for a new method and associated system that is capable of extracting the AVA or AVO information from the recorded seismic data while overcoming the problems noted above in the existing methods.

### SUMMARY OF THE INVENTION

According to an embodiment, there is a method for extracting amplitude-versus-reflection angle, or amplitude-versus-offset information from input data. The method includes receiving the input data d, which is indicative of a formation underground, receiving an initial earth model V that includes at least a pressure-wave velocity vₚ, calculating an updated, extended domain earth model Vₑ based on the input data d, and the initial earth model V, using a full waveform inversion process, wherein the updated, extended domain earth model Vₑ is expressed in an extended domain, transforming the updated, extended domain earth model Vₑ from the extended domain to an ordinary domain, which is different from the extended domain, to obtain an ordinary domain updated earth model, extracting the amplitude-versus-reflection angle or amplitude-versus-offset information from the ordinary domain updated earth model, and generating an image of a subsurface that is indicative of the formation in the subsurface, based on the extracted amplitude-versus-reflection angle or amplitude-versus-offset information. The subsurface is described by the input data d.

According to another embodiment, there is a method for extracting amplitude-versus-reflection angle or amplitude-versus-offset information from input data. The method includes receiving the input data d, which is indicative of a formation underground, receiving an initial earth model V that includes at least a pressure-wave velocity vₚ, calculating an updated, extended domain earth model Vₑ based on the input data d, and the initial earth model V, using a full waveform inversion process, wherein the updated, extended domain earth model Vₑ is expressed in an extended domain, applying an amplitude-versus-reflection angle or amplitude-versus-offset correction to the updated, extended domain earth model Vₑ to obtain a corrected, updated, extended domain earth model Vₑ, transforming the corrected, updated, extended domain earth model Vₑ from the extended domain to an ordinary domain, which is different from the extended domain, to obtain an ordinary domain updated earth model, extracting the amplitude-versus-reflection angle or amplitude-versus-offset information from the ordinary domain updated earth model, and generating an image of a subsurface that is indicative of the formation in the subsurface, based on the extracted amplitude-versus-reflection angle or amplitude-versus-offset information. The subsurface is described by the input data d.

### BRIEF DESCRIPTION OF THE DRAWINGS

For a more complete understanding of the present invention, reference is now made to the following descriptions taken in conjunction with the accompanying drawings, in which:

FIG. 1 is a schematic diagram of a marine based seismic acquisition system;

FIG. 2 is a schematic flow chart of a method that uses FWI for updating an earth's model and then generating an image of the subsurface based on the updated model;

FIG. 3 is a flow chart of a method for extracting AVA or AVO information from recorded data by using an extended domain earth model in an extended domain and then transforming the updated extended domain earth model to an ordinary domain for generating an image of the subsurface;

FIGS. 4A and 4B schematically illustrate a feature of an extended domain;

FIG. 5A illustrates an extended domain and FIG. 5B illustrates the data of FIG. 5A being transformed into an ordinary domain;

FIG. 6 is a flow chart of another method for extracting AVA or AVO information from recorded data by using an extended domain earth model in an extended domain and then transforming the updated extended domain earth model to an ordinary domain for generating an image of the subsurface;

FIGS. 7A to 7C illustrate reflection AVO for a synthetic elastically modeled event with reflection AVO derived from acoustic FWI;

FIG. 8 is a flow chart of a method of extracting AVA or AVO information using an elastic FWI and muted input data;

FIGS. 9A to 9C illustrate reflection AVO for a synthetic elastically modeled event with reflection AVO derived from the method of FIG. 8; and

FIG. 10 is a schematic diagram of a computing device that supports any of the methods discussed herein.

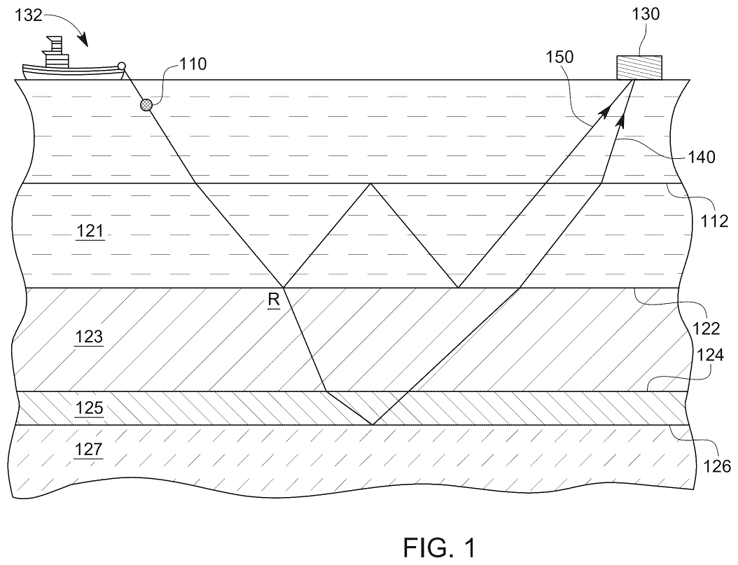

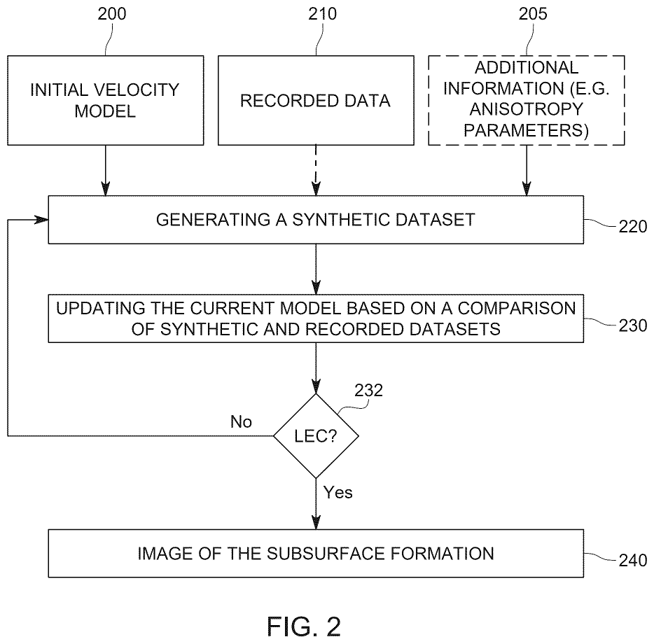

### DETAILED DESCRIPTION OF THE INVENTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed with regard to a modified FWI process for more accurately capturing amplitude variations with the reflection angle or offset, using terminology of seismic data processing. However, the embodiments to be discussed next are not limited to seismic data, but may be applied to other types of data, for example, electromagnetic wave data or acoustic data.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

The methods described herein could be applied to the field of subsurface exploration, for example, hydrocarbon exploration and development, geothermal exploration and development, and carbon capture and sequestration, or other natural resource exploration and exploitation. The methods could also be employed for surveying and monitoring for windfarm applications, both onshore and offshore, and also for medical imaging applications.

According to an embodiment, the FWI process is applied to calculate an extended domain earth model, which is then transformed into an ordinary domain, for example, at least one of reflection- and dip-angle domain. This novel feature of calculating the AVA or AVO information is now discussed in more detail. The term “domain” here is understood as a space in which the acquired seismic data (e.g., traces) is represented via a transformation. This transformation can be something as simple as, for example, a sorting process, or a more complex operation such as conversion from a time-sampled data set into a frequency sampled data set via a Fourier transform. Alternatively, a domain can be a physical representation of the subsurface derived from the acquired seismic data, such as an imaging or velocity model building process. There are many domains, like the shot domain, common mid-point (CMP) domain, offset domain, stack domain, reflection-angle domain, dip-angle domain, slant-stack (linear Radon) domain, Fourier domain, image domain, model domain, etc., and these domains are called herein “ordinary domains.” The gathering or representation of the seismic data (traces) in these domains results in the generation of a “gather.” Depending on the process that is used to gather the traces together, for example, via a physical attribute such as offset, or angle, or other parameter, the obtained gathers are called common-image (CIP) gather, or CMP gather, or offset-domain common-image gather (ODCIG), or angle-domain common-image gathers (ADCIG), slant-stack (linear Radon) gather, etc. The gathers and associated domains are not abstract mathematical concepts, as they correspond to physical reflections, refractions, refractions or other phenomena that affect the seismic waves in the subsurface. Further, the gathers and the domains provide a framework for describing images of the subsurface.

The various ordinary domains were introduced in geophysics for various reasons, for example, the shot domain is appropriate for resampling, trace editing, noise removal, static correction, the CMP domain is appropriate for deconvolution, deghosting, velocity analysis, multiple elimination, the offset domain is appropriate for iterative velocity models and analysis, migration and muting, and the stack domain is appropriate for post-stack processing, attribute analysis, AVO, etc. Thus, each domain is advantageous, from a mathematical point of view, for a certain application (or multiple applications).

The AVO and/or AVA analysis are typically performed in one of the ordinary domains discussed above. However, the inventors have realized that more accurate results may be obtained if the AVO and AVA analysis is performed in an extended domain. An extended domain differs from the ordinary domains discussed above because it adds additional degrees of freedom to an ordinary domain, typically achieved by adding nonphysical, redundant, dimensions to physical parameters. An example of an extended domain may be the subsurface offset domain (in x, y, z) of the image domain [1, 2], or the subsurface time-shift domain of the image domain [3], or the subsurface offset domain (in x, y, z) of the model domain [4], or any combination of these domains, or another domain.

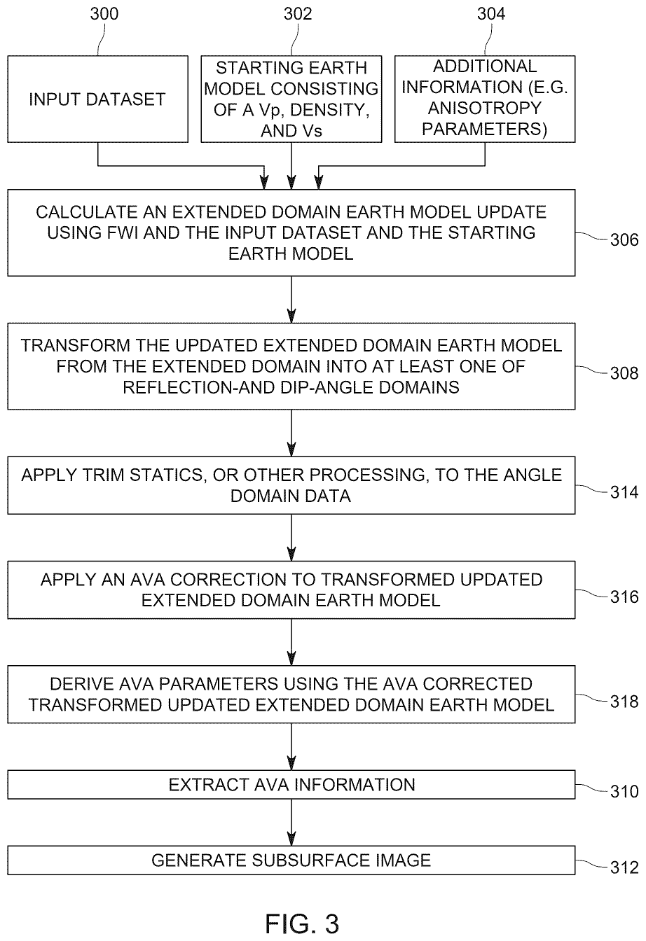

Thus, a method that uses an extended domain defined above, via an extended domain earth model Vₑ, is now discussed with regard to FIG. 3. The method includes a step 300 of receiving an input dataset d, which can be recorded with hydrophones, accelerometers, geophones, etc. This means that the input dataset d, which can be a seismic dataset, may include a pressure or a displacement or a velocity or an acceleration. No matter which specific quantity is measured by the sensor, all of them are described by an amplitude A and a phase φ. The purpose of the algorithm is to extract the amplitudes A, to update the starting earth model, and to generate an image of the subsurface that is indicative of various features of the subsurface, for example, an oil or gas reservoir.

The method further receives, in step 302, a starting earth model V, which includes, as a minimum, the pressure-wave velocity vₚ. The model may also include the density, and/or the shear-wave velocity vₛ, and/or any other earth related parameter. In step 304, the method may receive, optionally, any additional earth related information, for example, the anisotropy parameters. Other parameters, as discussed above, may be received in this step. In step 306, an extended domain earth model update Vₑ is calculated based on the input dataset d and the starting earth model V, in an extended domain. The starting earth model is, in one embodiment, converted into an extended domain starting earth model by setting the additional (e.g., non-physical) part of the extended domain starting earth model to be zero. The extended domain earth model update Vₑ is calculated in this embodiment using the FWI process. One skilled in the art would understand that another process may be used for updating the extended domain earth model update Vₑ, if so desired.

Once the extended domain earth model Vₑ has been updated, the method transforms, in step 308, the updated, extended domain earth model from the extended domain into an ordinary domain, for example, at least one of reflection- and dip-angle domains, which results in a transformed, updated, extended domain earth model. Note that the “ordinary” domain is defined herein as being any domain that is not an extended domain. In step 310, the method extracts the AVA or AVO information, for example, the amplitude of the recorded seismic data, from the transformed, updated, extended domain earth model. In step 312, the method generates an image of the surveyed subsurface based on the extracted AVA or AVO information. Note that this image is indicative of the various layers or formations present in the subsurface, and, in some cases, of an oil and gas reservoir, or other resources reservoir.

The method may also include some optional steps, which are performed before the step 310 of extracting the AVA or AVO information and after the step 308 of transforming the earth model from the extended domain to the ordinary domain. One such optional step is step 314 of applying trim statics, or other processing, to the angle domain data of step 308. Another optional step may be step 316 of applying an AVA correction to the transformed, updated, extended domain earth model. Another optional step may be step 318 of deriving the AVA parameters using the AVA corrected, transformed, updated, extended domain earth model.

Returning to step 306, the used FWI may be an acoustic FWI process, or an elastic FWI process. Step 306 may update at least one parameter of the model, for example, the speed vₚ, or the speed vₚ and the density, or the speed vₚ and any other parameter of the model. In one application, step 306 updates the extended domain earth model in one or more of the extended domains. For example, step 306 may update the extended domain earth model while operating in one or any combination of the subsurface-offset or time-shift domain extensions.

Step 308 involves transforming the extended domain earth model from the extended domain to the ordinary domain. Such a transform may include a slant-stack in space or time domains, or a radial-trace transform in the Fourier domain. Step 316 applies an AVA or AVO correction. The AVA or AVO correction may be based on one of the Zoeppritz equation, the Shuey approximation, or another approximation.

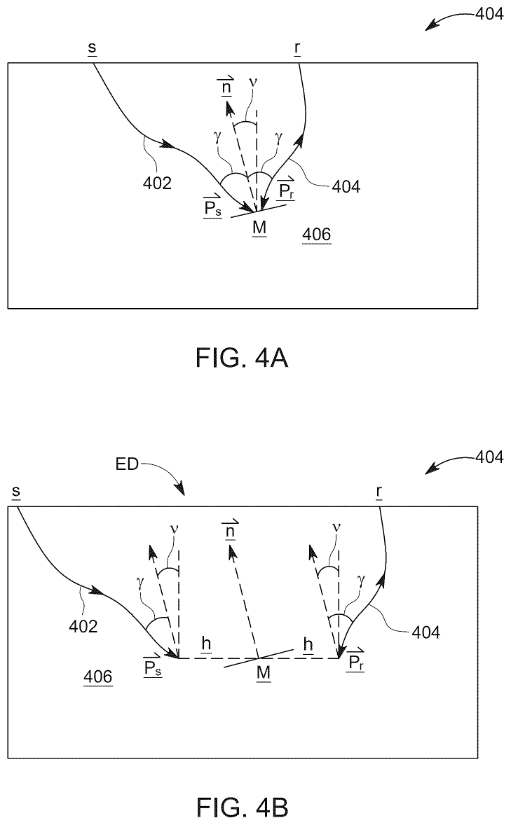

The extended-domain concept introduced in the embodiment illustrated in FIG. 3 works with the FWI processing and its model inversions for other purposes, not only for the extraction of AVA or AVO information. In this regard, for the standard imaging/migration of seismic data, these extended domains are known to allow the possibility of an accurate estimate of 2D or 3D reflection angle information by analysis of the data in the extended domain (see, [5, 6]). In general, this reflection angle estimation will be more accurate than other commonly used techniques, such as from post-FWI ray-tracing through the earth model, or pre-FWI muting of the input data. The extended domains are also known to allow the possibility of an accurate amplitude extraction by appropriate migration and analysis of the data in the extended domain (see, [7, 8]). In this regard, an example of an extended domain is illustrated with regard to FIGS. 4A and 4B, which are reproduced from [8]. FIG. 4A illustrates the interaction between the incident 402 and scattered 404 plane waves at zero subsurface offset while FIG. 4B shows the same for a finite subsurface offset h, and this interaction results in an image at the subsurface midpoint M. Note that these two figures show a source s and a receiver r located at the surface 404, and the midpoint M is located within the subsurface 406. The figure also shows the scattering angle γ and the dip angle v. The subsurface offset (which is different from the source-receiver offset) in the extended domain is defined as the Cartesian offset vector h connecting the sunken shot 402 and the sunken receiver 404, in the subsurface 406, and it involves an action at a distance between the incident and scattered wavefields. The image I, extended by the subsurface offset h, as illustrated in FIG. 4B, takes the form:

$$I ( x , h / 2 ) = \int {dx}_{r} \int {dx}_{s} \int dt \frac{{\partial }^{2}}{\partial {t}^{2}} d ( {x}_{r} , t ; {x}_{s} ) \times \int d τ G ( x + h / 2 , t - τ ; {x}_{r} ) G ( x - h / 2 , τ ; {x}_{s} ) , \qquad ( 3 )$$

where xᵣ is the position of the receiver, xₛ is the position of the source, x is the image location in the subsurface, G(x, t) is the Green's function, and t is the migration time.

The meaning of the subsurface offset h, which can be a vector or a scalar, and which is the reason for the “extended” domain name, is that this domain now allows reflection at a distance. This is clearly a nonphysical extension, and data fit is thus achievable by violating the physical rule of wave propagation. Correspondingly, this approach produces an extended image volume l depending not only on the spatial coordinate x, but also on the subsurface offset h. Thus, the subsurface offset h extends the domain by introducing a new dimension.

For a perfectly known velocity model, action will take place only at zero subsurface offset (i.e., the physical offset), and thus, the extended image will be perfectly focused at zero offset. Likewise, incorrect velocity will defocus the image and may produce a fake reflector image at nonzero offset (i.e., nonphysical offset). As described above, data fit is still achievable, despite the incorrect velocity model, by violating the physics of wave propagation via the nonzero subsurface offsets. The subsurface offset extension illustrated in FIG. 4B can be restricted by setting one of its subsurface spatial coordinates to zero, but these details are beyond the scope of this disclosure.

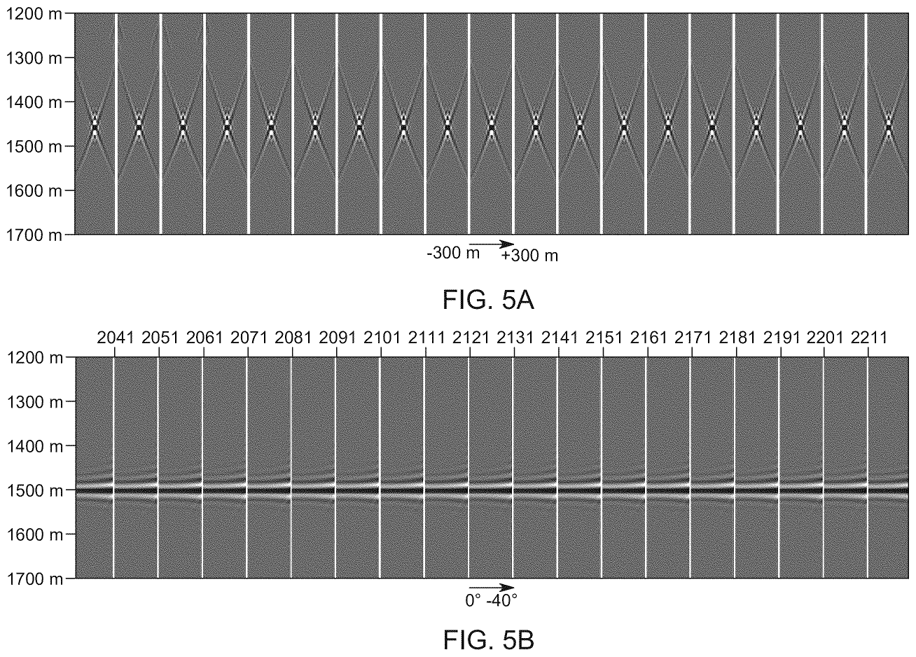

An actual manifestation of an extended domain and its transformation to an ordinary domain is shown in FIGS. 5A and 5B. FIG. 5A shows seismic traces grouped as subsurface offset gathers in the subsurface offset domain (extended domain) in x, while FIG. 5B shows the same seismic traces transformed into the angle domain (ordinary domain) and represented as reflection angle gathers. In this regard, note that the X axis of FIG. 5A shows the subsurface offset h discussed above while the X axis of FIG. 5B shows the corresponding reflections angle while axis Y shows the depth.

Returning to the method of FIG. 3, step 306 of calculating the extended domain earth model with the proposed FWI approach may use the Born extended domain modeling [4] to generate single-scattered forward modeled data. The mathematics of the Born extended domain modeling is not repeated herein, but it is incorporated by reference from [4]. This single-scattered forward modeled data from the Born extended domain modeling comes via a plurality of interactions for a range of subsurface offsets h (or time-shifts) of a forward propagated wavefield 402 within the extended domain earth model. The updated extended domain earth model Vₑ coming from the proposed FWI approach can then be used to extract the AVA or AVO information.

In this embodiment or another embodiment, the modeling step 306 of the proposed FWI approach may involve forward propagating a source wavefield 402 through an extended domain earth model Vₑ characterized by a plurality of density volumes, for a range of subsurface offsets h (or time-shifts), between the source wavefield 402 and the respective density volume. The updated extended domain earth model coming from the proposed FWI approach can then be used to extract the AVA or AVO information.

In this or another embodiment, the modeling step 306 of the proposed FWI approach may involve forward propagating a source wavefield 402 through an extended domain earth model Vₑ characterized by a plurality of vₚ volumes for a range of subsurface offsets h (or time-shifts), between the source wavefield 402 and the respective vₚ volume. The updated extended domain earth model coming from the proposed FWI approach can then be used to extract the AVA or AVO information.

Various steps or modifications may be added to the method discussed above with regard to FIG. 3. For example, the updated model Vₑ is useable to locate any natural resource, geothermal reservoir, in the explored underground structure. The AVA or AVO parameters discussed above may relate to an amplitude intercept and an amplitude gradient with angle. The AVA correction may be applied to the transformed updated extended domain model. The AVA parameters may be derived using the AVA corrected transformed updated extended domain model.

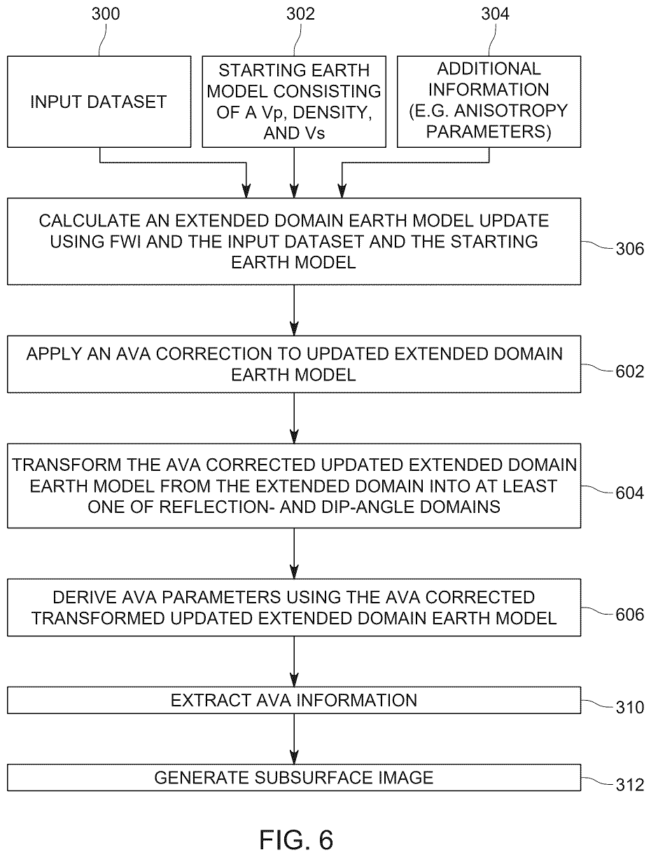

The method discussed above may be modified to still be able to extract AVA or AVO information by using the extended domain approach. This new method is illustrated in FIG. 6 and includes some of the steps of the method of FIG. 3. The description of those steps is omitted herein. After the step 306 of calculating the extended domain earth model update Vₑ using the input dataset and the starting earth model, based on the FWI, the method applies in step 602 an AVA or AVO correction to the updated, extended domain earth model to obtain a corrected, updated, extended domain, earth model. As previously discussed, any known AVA or AVO correction may be applied. Then, the method transforms in step 604 the AVA or AVO corrected, updated, extended domain, earth model, from the extended domain into an ordinary domain, e.g., at least one of reflection- and dip-angle domains, to generate a transformed, corrected, updated, extended domain earth model. Such a transform may include a slant-stack in space or time domains, or a radial-trace transform in the Fourier domain. Then, the method extracts in step 310 the AVA or AVO information from the transformed, corrected, updated, extended domain earth model and generates the subsurface image in step 312.

Optionally, the method may derive in step 606 the AVA or AVO parameters using the AVA corrected, transformed, updated, extended domain earth model. Note that in one embodiment step 310 looks at the raw AVA data, whereas step 606 is fitting the AVA parameters to this raw AVA data. Similar to the method of FIG. 3, the FWI used in step 306 can be an acoustic FWI process or an elastic FWI process, and the extended domain earth model updates at least one of density and vₚ. The extended domain earth model update of step 306 operates in one or any combination of the subsurface-offset or time-shift domain extensions. The AVA or AVO correction of step 602 is based on one of the Zoeppritz equation, the Shuey approximation, or another approximation.

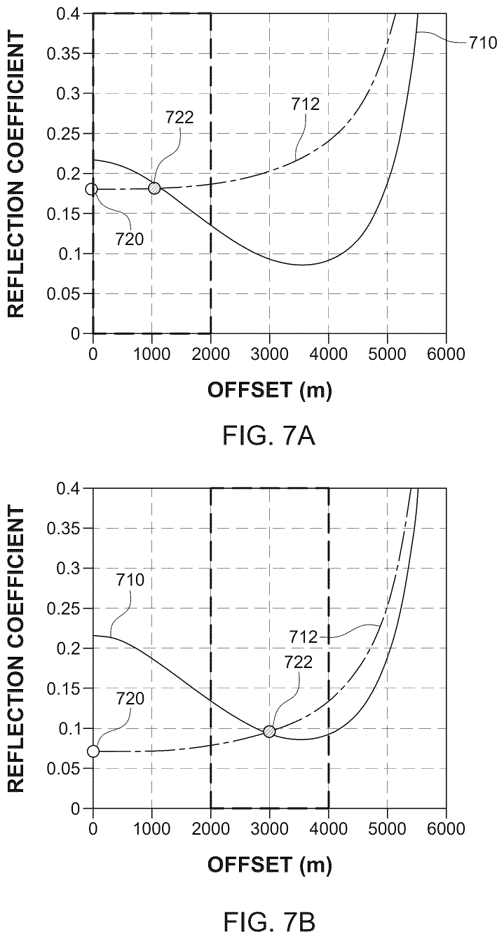

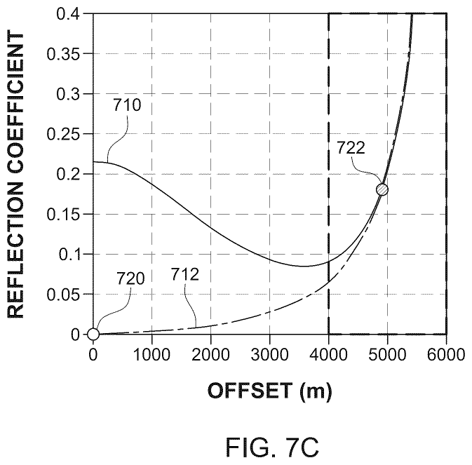

In another embodiment, the AVA or AVO information may be extracted using the FWI in the ordinary domain, with muted input data. Before discussing such an approach, an example of the problems facing the current AVA or AVO information extraction when the reflection angles vary is now discussed. FIGS. 7A to 7C compare reflection AVO for a synthetic elastically modeled event in the solid line 710 (considered here to be the true elastic curve, i.e., vₚ/vₛ=2.0) with reflection AVO derived from acoustic FWI in the dotted line 712 (acoustic AVO with vₛ=0.0). The three different sets of results correspond to acoustic FWI run for input offset ranges 0-2000 m (FIG. 7A), 2000-4000 m (FIG. 7B) and 4000-6000 m (FIG. 7C). The raw FWI amplitude output is given by the open dots 720, representing the zero-angle equivalent amplitude in each set of results. Based on the acoustic FWI velocity and density information, the open dots 720 are corrected along the acoustic AVO curve (via, for example, a 2- or 3-term Shuey, or Zoeppritz, equation), ideally to the crossing point between the true elastic and acoustic curves (the closed dot 722). Although, after correction, the acoustic amplitude is representative of the average elastic amplitude within the offset range, the amplitude variation with offset within the offset range in question can be different between the elastic and acoustic curves. On field data, the offset corresponding to the crossing point is unknown and there is a need to choose an offset to correct to. On field data containing noise and real-world experimental errors, there is always ambiguity in that choice and this can lead to an inaccurate representation of the AVO information. While this example illustrates data in different offset ranges, data may alternatively be input in different reflection angle ranges.

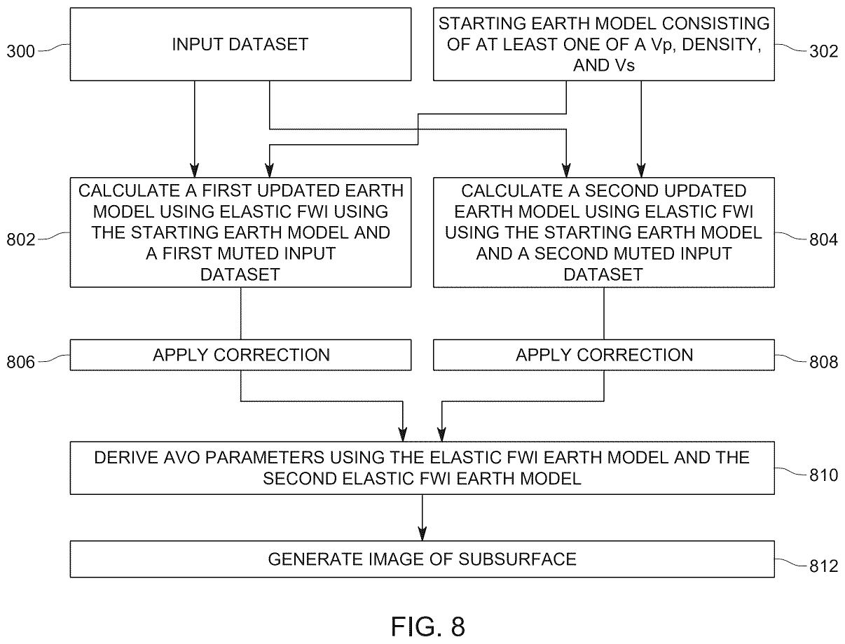

To overcome the problems illustrated in FIGS. 7A to 7C, a novel approach for extracting AVO or AVA information while using input muted data and FWI is now discussed with regard to FIG. 8. In this embodiment, the FWI is an elastic FWI and it is applied on data muted with different offset or reflection angle ranges, to capture AVO information. Further, the terms “AVO” and “AVA” are used interchangeably herein to mean an amplitude variation with varying reflection angle. The method includes steps 300 and 304 discussed above. Note that the starting earth model V may include at least vₚ, or a combination of vₚ and any of the other parameters discussed herein, for example, at least one of density and vₛ. In step 304, the method may receive, optionally, any additional earth related information, for example, the anisotropy parameters. Other parameters, as discussed above, may be received in this step.

In step 802, the method calculates a first updated earth model V₁ using the elastic FWI, the starting earth model V and a first muted input dataset d₁, which is a subset of the input data d. In step 804, the method calculates a second updated earth model V₂ using the elastic FWI, the starting earth model V and a second muted input dataset d₂, which is also a subset of the input data d. As discussed above, at least the vₚ is updated during steps 802 and 804. Note that the first muted input data d₁ is obtained by muting the input data d with a first mute function, and the second muted input data d₂ is obtained by muting the input data d with a second mute function, which is different from the first mute function. In one application, the first and second mute functions are complementary, i.e., if both functions are applied to the input data d, the result is a void set.

In step 806, which is optional, it is possible to apply an AVO correction to the first elastic FWI earth model V₁ and in step 808, which is also optional, it is possible to apply an AVO correction to the second elastic FWI earth model V₂. Any known AVO correction method may be applied in these steps. In step 810, the method derives the AVO parameters using the first elastic FWI earth model and the second elastic FWI earth model. For example, it is possible to take the data generated by each of the steps 802 and 804 (or 806 and 808, if the corrected data is used) and the entire data is used to generate the AVO information, for example, the Zoeppritz equation, the Shuey approximation, or another approximation. Then, in step 812, the image of the subsurface is generated based on the extracted AVO information.

In one application, the first and second mutes d₁ and d₂ are dependent on the starting earth model velocities from step 302. In this application or another application, the first and second muted datasets correspond to different source-receiver offset ranges for a given two-way travel-time. In one application, the calculated AVO parameters may relate to an amplitude intercept and an amplitude gradient with offset or angle.

Similar to the other methods discussed herein, the input earth model V may come from travel-time tomography, acoustic FWI, elastic FWI, reservoir inversion analysis or other earth model building approaches. These methods may use diving waves, diffractions, guided waves, or reflections.

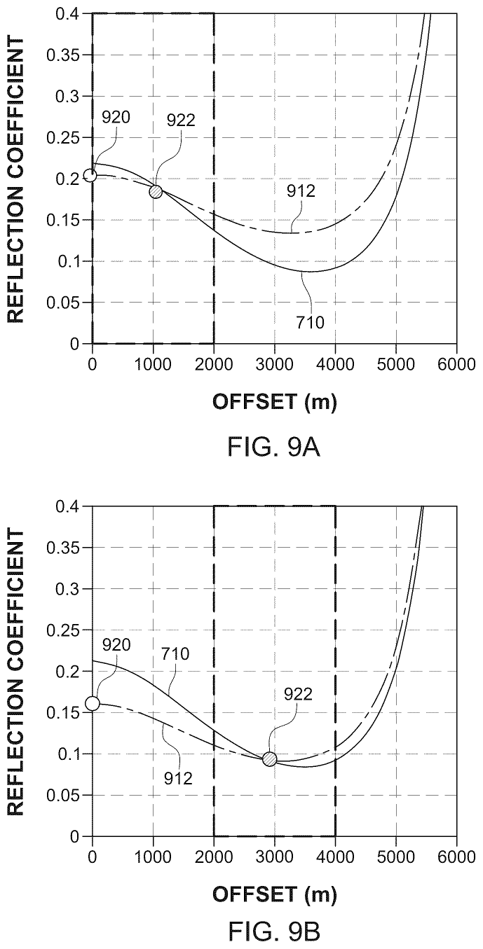

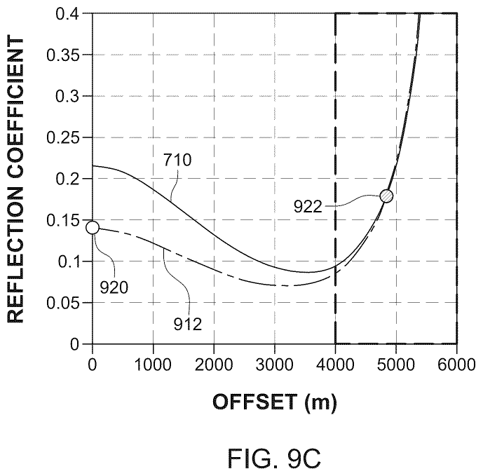

In the above embodiment, the input data muting that resulted in the first muted input dataset d₁ and the second muted dataset d₂ may relate to first and second reflection angle ranges (e.g., 0-12 degrees and 12-24 degrees, but other values may be used). The angle or offset ranges may or may not overlap. Compared to an equivalent acoustic FWI application (as illustrated in FIGS. 7A to 7C), the use of elastic FWI with approximate, yet realistic, vₛ information in steps 802 and 804 will more accurately represent the seismic amplitude variation with reflection angle in the range in question, as illustrated in FIGS. 9A to 9C. In these figures, it can be seen that the AVO corrected closed dots 922 are in the same location as in FIGS. 7A to 7C, following the correction from their raw FWI zero-angle equivalent amplitude output (open dots 920), but that the amplitude variation with offset derived from the elastic FWI better approximates the true elastic AVO across the offset range in question. Note that curve 912 indicates the approximate elastic AVO, with vₚ/vₛ=2.5. This can lead to a more accurate representation of the true AVO information than would be obtained from the acoustic FWI, especially when this process is applied to field data that contains noise and real-world experimental errors, even if only approximate vₛ information is available. On field data, the position along the x-axis (offset or angle), where one can choose to compute the correction, will have some error associated with it, in the sense that it will not coincide with the unknown offset (or angle) where the approximate and true elastic curves intersect. However, because the shape of the true elastic curve is closer to that of the approximate elastic curve than it is to that of the acoustic curve, the AVO correction obtained from the approximate elastic curve will be less sensitive than the acoustic approach to the error in the choice of the offset or angle where the correction is computed.

An alternative approach may involve using the first updated earth model V₁ from step 802 as input to the elastic FWI application using the second muted input dataset, i.e, V₁ may be the input to step 804.

Various additional steps may be performed with the method illustrated in FIG. 8. For example, in one application the elastic FWI honors an input vₛ earth model but does not update the input vₛ earth model. In this application or another application, it is possible that the elastic FWI updates an input vₛ earth model based on a provided vₚ/vₛ ratio. In yet another application, the starting model includes vₚ and density, and the elastic FWI applications on the first and second muted datasets update the vₛ. In one application, the AVO parameters contain at least one of an intercept and a gradient. In this or another application, the first and second mute functions correspond to different source-receiver offset ranges for different two-way travel-times or the first and second mute functions relate to substantially different angle ranges. The first and second mute functions may be dependent upon the starting earth model. In one application, it is possible that the first and second mute functions do not overlap. However, in another application, the first and second mute functions overlap. In one application, the first and second mute functions overlap by less than a width of the first or second mute function.

In one embodiment, the method of FIG. 8 for extracting amplitude-versus-reflection angle or amplitude-versus-offset information from input data may include the following selected steps. The method includes a step 300 of receiving the input data d, which is indicative of a formation underground, a step 302 of receiving an initial earth model V that includes at least a pressure-wave velocity vₚ, a step 802 of calculating a first updated earth model V₁ based on a first muted input data d₁, and the initial earth model V, and using an elastic full waveform inversion process, a step 804 of calculating a second earth model V₂ based on a second muted input data d₂, and the initial earth model V, and using the elastic full waveform inversion process; a step 810 of extracting the amplitude-versus-reflection angle or amplitude-versus-offset information from the first and second updated earth models, and a step 812 of generating an image of a subsurface that is indicative of the formation in the subsurface, based on the extracted amplitude-versus-reflection angle or amplitude-versus-offset information. The subsurface is described by the input data d, and the first and second muted input data d₁ and d₂ are subsets of the input data d.

In one variation, the first muted input data d₁ is obtained by muting the input data d with a first mute function, and the second muted input data d₂ is obtained by muting the input data d with a second mute function, which is different from the first mute function. The method may further include applying an amplitude-versus-reflection angle or amplitude-versus-offset correction to the first updated earth model, before calculating the amplitude-versus-reflection angle or amplitude-versus-offset information, and applying the amplitude-versus-reflection angle or amplitude-versus-offset to the second updated earth model, before calculating the amplitude-versus-reflection angle or amplitude-versus-offset information. In this embodiment or a variation of this embodiment, the initial earth model V includes a pressure-shear velocity vₛ, but the elastic full waveform inversion process does not update the vₛ, the steps of calculating the first and second earth models are based on a provided vₚ/vₛ ratio, the amplitude-versus-reflection angle or amplitude-versus-offset information is related to an amplitude intercept and an amplitude gradient with angle, the amplitude-versus-reflection angle or amplitude-versus-offset correction is based on the Zoeppritz equation or Shuey approximation, the first and second muted input data correspond to different source-receiver offset ranges for different two-way travel-times, and/or the first and second mute functions relate to substantially different angle ranges.

In addition to the benefits discussed until now, elastic FWI also has improved accuracy compared to acoustic FWI for elastic effects such as guided waves, surface waves, salt-sediment contrasts or chalk-sediment contrasts. The method described with regard to FIG. 8 may be applied to the field of subsurface exploration, for example, hydrocarbon exploration and development, geothermal exploration and development, and carbon capture and sequestration, or other natural resource exploration and exploitation. It could also be employed for surveying and monitoring for windfarm applications, both onshore and offshore, and also for medical imaging applications.

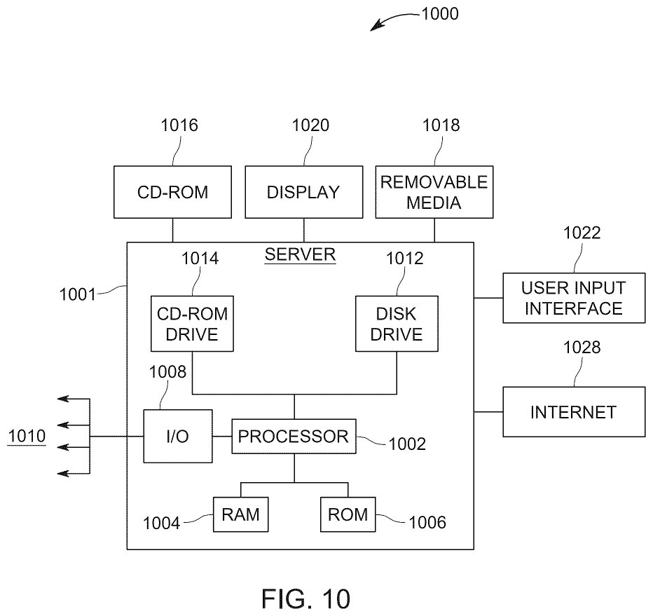

The above-discussed procedures and methods may be implemented in a computing device as illustrated in FIG. 10. Hardware, firmware, software or a combination thereof may be used to perform the various steps and operations described herein. The computing device 1000 is suitable for performing the activities described in the above embodiments and may include a server 1001. Such a server 1001 may include a central processor (CPU) 1002 coupled to a random access memory (RAM) 1004 and to a read-only memory (ROM) 1006. ROM 1006 may also be other types of storage media to store programs, such as programmable ROM (PROM), erasable PROM (EPROM), etc. Processor 1002 may communicate with other internal and external components through input/output (I/O) circuitry 1008 and bussing 1010 to provide control signals and the like. Processor 1002 carries out a variety of functions as are known in the art, as dictated by software and/or firmware instructions.

Server 1001 may also include one or more data storage devices, including hard drives 1012, CD-ROM drives 1014 and other hardware capable of reading and/or storing information, such as DVD, etc. In one embodiment, software for carrying out the above-discussed steps may be stored and distributed on a CD-ROM or DVD 1016, a USB storage device 1018 or other form of media capable of portably storing information. These storage media may be inserted into, and read by, devices such as CD-ROM drive 1014, disk drive 1012, etc. Server 1001 may be coupled to a display 1020, which may be any type of known display or presentation screen, such as LCD, plasma display, cathode ray tube (CRT), etc. A user input interface 1022 is provided, including one or more user interface mechanisms such as a mouse, keyboard, microphone, touchpad, touch screen, voice-recognition system, etc.

Server 1001 may be coupled to other devices, such as CT scan, MRI machine, or any other data imaging systems. The server may be part of a larger network configuration as in a global area network (GAN) such as the Internet 1028, which allows ultimate connection to various landline and/or mobile computing devices.

As described above, the apparatus 1000 may be embodied by a computing device. However, in some embodiments, the apparatus may be embodied as a chip or chip set. In other words, the apparatus may comprise one or more physical packages (e.g., chips) including materials, components and/or wires on a structural assembly (e.g., a baseboard). The structural assembly may provide physical strength, conservation of size, and/or limitation of electrical interaction for component circuitry included thereon. The apparatus may therefore, in some cases, be configured to implement an embodiment of the present invention on a single chip or as a single “system on a chip.” As such, in some cases, a chip or chipset may constitute means for performing one or more operations for providing the functionalities described herein.

The processor 1002 may be embodied in a number of different ways. For example, the processor may be embodied as one or more of various hardware processing means such as a coprocessor, a microprocessor, a controller, a digital signal processor (DSP), a processing element with or without an accompanying DSP, or various other processing circuitry including integrated circuits such as, for example, an ASIC (application specific integrated circuit), an FPGA (field programmable gate array), a microcontroller unit (MCU), a hardware accelerator, a special-purpose computer chip, or the like. As such, in some embodiments, the processor may include one or more processing cores configured to perform independently. A multi-core processor may enable multiprocessing within a single physical package. Additionally or alternatively, the processor may include one or more processors configured in tandem via the bus to enable independent execution of instructions, pipelining and/or multithreading.

In an example embodiment, the processor 1002 may be configured to execute instructions stored in the memory device 1004 or otherwise accessible to the processor. Alternatively, or additionally, the processor may be configured to execute hard coded functionality. As such, whether configured by hardware or software methods, or by a combination thereof, the processor may represent an entity (e.g., physically embodied in circuitry) capable of performing operations according to an embodiment of the present invention while configured accordingly. Thus, for example, when the processor is embodied as an ASIC, FPGA or the like, the processor may be specifically configured hardware for conducting the operations described herein. Alternatively, as another example, when the processor is embodied as an executor of software instructions, the instructions may specifically configure the processor to perform the algorithms and/or operations described herein when the instructions are executed. However, in some cases, the processor may be a processor of a specific device (e.g., a pass-through display or a mobile terminal) configured to employ an embodiment of the present invention by further configuration of the processor by instructions for performing the algorithms and/or operations described herein. The processor may include, among other things, a clock, an arithmetic logic unit (ALU) and logic gates configured to support operation of the processor.

It will be understood that, although the terms first, second, etc. may be used herein to describe various elements, these elements should not be limited by these terms. These terms are only used to distinguish one element from another. For example, a first object or step could be termed a second object or step, and, similarly, a second object or step could be termed a first object or step, without departing from the scope of the present disclosure. The first object or step, and the second object or step, are both, objects or steps, respectively, but they are not to be considered the same object or step.

The terminology used in the description herein is for the purpose of describing particular embodiments and is not intended to be limiting. As used in this description and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

The disclosed embodiments provide various methods for extracting AVA or AVO information by using FWI and an extended domain, or elastic FWI and muted input data. It should be understood that this description is not intended to limit the invention. On the contrary, the embodiments are intended to cover alternatives, modifications and equivalents, which are included in the spirit and scope of the invention as defined by the appended claims. Further, in the detailed description of the embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

### REFERENCES

The entire content of all the publications listed herein is incorporated by reference in this patent application.
[1] Rickett, J. E., and Sava, P. C. Offset and angle-domain common image-point gathers for shot-profile migration, GEOPHYSICS, VOL. 67, NO. 3, P. 883-889.
[2] Sava, P. C. and Fomel, S. Angle-domain common-image gathers by wavefield continuation methods, GEOPHYSICS, VOL. 68, NO. 3, P. 1065-1074.
[3] Sava, P. C. and Fomel, S. Time-shift imaging condition in seismic migration, GEOPHYSICS, VOL. 71, NO. 6, P. S209-S217.
[4] Hou, J. and Symes, W. W. Inversion velocity analysis in the subsurface-offset domain, GEOPHYSICS, VOL. 83, NO. 2, P. R189-R200.
[5] Fomel, S. Theory of 3-D angle gathers in wave-equation imaging: 74th SEG Annual International Meeting, Expanded Abstracts, 1053-1056.
[6] Fomel, S. Theory of 3-D angle gathers in wave-equation seismic imaging. J Petrol Explor Prod Technol, 1, p 11-16.
[7] Zhang, Y., Xu, S., Bleistein, N. and Zhang, G. True-amplitude, angle-domain, common-image gathers from one-way wave-equation migrations. GEOPHYSICS, VOL. 72, NO. 1, P. S49-S58.
[8] Dafni, R. and Symes, W. W. Scattering and dip angle decomposition based on subsurface offset extended wave-equation migration, GEOPHYSICS, VOL. 81, NO. 3, P. S119-S138.

1. A method for extracting amplitude-versus-reflection angle, or amplitude-versus-offset information from input data, the method comprising:
receiving the input data d, which is indicative of a formation underground;
receiving an initial earth model V that includes at least a pressure-wave velocity vₚ;
calculating an updated, extended domain earth model Vₑ based on the input data d, and the initial earth model V, using a full waveform inversion process, wherein the updated, extended domain earth model Vₑ is expressed in an extended domain;
transforming the updated, extended domain earth model Vₑ from the extended domain to an ordinary domain, which is different from the extended domain, to obtain an ordinary domain updated earth model;
extracting the amplitude-versus-reflection angle or amplitude-versus-offset information from the ordinary domain updated earth model; and
generating an image of a subsurface that is indicative of the formation in the subsurface, based on the extracted amplitude-versus-reflection angle or amplitude-versus-offset information,
wherein the subsurface is described by the input data d.

2. The method of claim 1, wherein the full waveform inversion process comprises:
generating a synthetic data set corresponding to the input data d, using the initial earth model V;
estimating a misfit function between the input data d and the synthetic data; and
updating the initial earth model V so that the misfit function has a value below a given threshold, to generate the updated extended domain earth model Vₑ.

3. The method of claim 1, wherein the extended domain is a subsurface offset domain or a time-shift domain and the ordinary domain is an angle domain.

4. The method of claim 3, wherein the angle domain is a reflection- or dip-angles domain.

5. The method of claim 1, wherein the step of transforming includes a slant-stack in space or time domains or a radial-trace transform in the Fourier domain.

6. The method of claim 1, further comprising:
applying trim statics to the ordinary domain.

7. The method of claim 1, wherein the amplitude-versus-reflection angle or amplitude-versus-offset information is related to an intercept and an amplitude gradient with angle.

8. The method of claim 1, further comprising:
applying a correction process to the ordinary domain updated earth model,
wherein the correction process is based on the Zoeppritz equation or Shuey approximation.

9. The method of claim 1, wherein an ordinary domain is a space in which the seismic data is represented via a transformation and an extended domain differs from an ordinary domain by adding additional degrees of freedom to the ordinary domain.

10. The method of claim 1, wherein the FWI is an elastic FWI process and the input data is seismic data.

11. A method for extracting amplitude-versus-reflection angle or amplitude-versus-offset information from input data, the method comprising:
receiving the input data d, which is indicative of a formation underground;
receiving an initial earth model V that includes at least a pressure-wave velocity vₚ;
calculating an updated, extended domain earth model Vₑ based on the input data d, and the initial earth model V, using a full waveform inversion process, wherein the updated, extended domain earth model Vₑ is expressed in an extended domain;
applying an amplitude-versus-reflection angle or amplitude-versus-offset correction to the updated, extended domain earth model Vₑ to obtain a corrected, updated, extended domain earth model Vₑ;
transforming the corrected, updated, extended domain earth model Vₑ from the extended domain to an ordinary domain, which is different from the extended domain, to obtain an ordinary domain updated earth model;
extracting the amplitude-versus-reflection angle or amplitude-versus-offset information from the ordinary domain updated earth model; and
generating an image of a subsurface that is indicative of the formation in the subsurface, based on the extracted amplitude-versus-reflection angle or amplitude-versus-offset information,
wherein the subsurface is described by the input data d.

12. The method of claim 11, wherein the full waveform inversion process comprises:
generating a synthetic data set corresponding to the input data d, using the initial earth model V;
estimating a misfit function between the input data d and the synthetic data; and
updating the initial earth model V so that the misfit function has a value below a given threshold, to generate the updated, extended domain, earth model Vₑ.

13. The method of claim 11, wherein the extended domain is a subsurface offset domain or a time-shift domain.

14. The method of claim 13, wherein the ordinary domain is an angle domain.

15. The method of claim 14, wherein the angle domain is a reflection- and dip-angles domain.

16. The method of claim 11, wherein the amplitude-versus-reflection angle or amplitude-versus-offset information is related to an amplitude intercept and an amplitude gradient with angle.

17. The method of claim 11, wherein the amplitude versus reflection angle or offset correction is based on Zoeppritz equation or Shuey approximation.

18. The method of claim 11, wherein the FWI is an elastic FWI process and the input data is seismic data.

19. The method of claim 11, wherein the step of transforming includes a slant-stack in space or time domains or a radial-trace transform in the Fourier domain.

20. The method of claim 11, wherein an ordinary domain is a space in which the seismic data is represented via a transformation and an extended domain differs from the ordinary domain by adding additional degrees of freedom to the ordinary domain.
